(19) United States
(12) Patent Application Publication
(10) Pub. No.: US 2026/0247924 A1
(43) Pub. Date: Aug. 20, 2026

(54) MEASUREMENT METHOD, MEASUREMENT DEVICE, MASTER PLATE MANUFACTURING METHOD, AND SEMICONDUCTOR DEVICE MANUFACTURING METHOD

(71) Applicant: Kioxia Corporation, Minato-ku, Tokyo (JP)

(72) Inventors: Taiki ITO, Kawasaki (JP); Kazuki HAGIHARA, Yokohama (JP)

(73) Assignee: Kioxia Corporation, Minato-ku, Tokyo (JP)

(21) Appl. No.: 19/324,435

(22) Filed: Sep. 10, 2025

(30) Foreign Application Priority Data
Dec. 18, 2024 (JP) 2024-222013

(51) Int. Cl. H10P 74/20; G03F 1/82; G06F 30/392

(52) U.S. Cl. CPC H10P 74/203; G03F 1/82; G06F 30/392

(57) ABSTRACT

A measurement method includes acquiring image data including a plurality of first patterns; identifying a plurality of first measurement regions in the image data; measuring a feature value of each of the plurality of first measurement regions using the image data, and forming a first array; acquiring design data including a plurality of second patterns; identifying a plurality of second measurement regions in the design data; measuring a feature value of each of the plurality of second measurement regions using the design data, and forming a second array; performing a statistical process using the first array and the second array; and based on a result of the statistical process, obtaining a desired feature value by matching the plurality of first patterns with the plurality of second patterns.

### CROSS-REFERENCE TO RELATED APPLICATION

This application is based upon and claims the benefit of priority from Japanese Patent Application No. 2024-222013, filed Dec. 18, 2024, the entire contents of which are incorporated herein by reference.

### FIELD

Embodiments described herein relate generally to a measurement method, a measurement device, a master plate manufacturing method, and a semiconductor device manufacturing method.

### BACKGROUND

In a step of manufacturing a master plate including a plurality of actual patterns, a feature value of the actual pattern is measured, and the master plate is evaluated according to a measurement result. In the step of manufacturing the master plate, it is desired to improve the measurement accuracy of the feature value of the actual pattern.

### DESCRIPTION OF THE DRAWINGS

FIG. 1 is a block diagram showing a configuration of a manufacturing system including a measurement device according to a first embodiment.

FIG. 2 is a flowchart showing an operation of the manufacturing system including the measurement device according to the first embodiment.

FIG. 3 is a block diagram showing a configuration of the measurement device according to the first embodiment.

FIG. 4 is a diagram showing a configuration of a measurement mechanism according to the first embodiment.

FIG. 5 is a flowchart showing a measurement process according to the first embodiment.

FIG. 6 is a diagram showing a configuration of a measurement target according to the first embodiment.

FIG. 7 is a flowchart showing a dimension data generation process according to the first embodiment.

FIGS. 8A to 8C are diagrams showing image data and contour data according to the first embodiment.

FIG. 9 is a flowchart showing collation with drawing data according to the first embodiment.

FIGS. 10A and 10B are diagrams showing the drawing data according to the first embodiment.

FIGS. 11A to 11C are diagrams showing the check of frequency distributions according to the first embodiment.

FIG. 12 is a flowchart showing a dimension data generation process according to a second embodiment.

FIG. 13 is a diagram showing contour data according to the second embodiment.

FIG. 14 is a flowchart showing a process of collating the drawing data according to the second embodiment.

FIGS. 15A to 15C are diagrams showing drawing data according to the second embodiment.

FIG. 16 is a diagram showing an evaluation of correlation according to the second embodiment.

FIG. 17 is a flowchart showing a measurement process according to a third embodiment.

FIG. 18 is a flowchart showing collation with drawing data according to the third embodiment.

FIG. 19 is a flowchart showing an operation of a manufacturing system including a measurement device according to a fourth embodiment.

### DETAILED DESCRIPTION

Embodiments provide a measurement method, a measurement device, a master plate manufacturing method, and a semiconductor device manufacturing method capable of improving a measurement accuracy of a feature value of an actual pattern.

In general, according to one embodiment, a measurement method is provided. The measurement method includes acquiring image data including a plurality of first patterns; identifying a plurality of first measurement regions in the image data; measuring a feature value of each of the plurality of first measurement regions using the image data, and forming a first array; acquiring design data including a plurality of second patterns; identifying a plurality of second measurement regions in the design data; measuring a feature value of each of the plurality of second measurement regions using the design data, and forming a second array; performing a statistical process using the first array and the second array; and based on a result of the statistical process, obtaining a desired feature value by matching the plurality of first patterns with the plurality of second patterns.

A measurement device according to an embodiment will be described in detail below with reference to the accompanying drawings. The present disclosure is not limited to the embodiments.

### First Embodiment

In the measurement device according to the first embodiment, in a step of manufacturing a master plate including a plurality of actual patterns, a feature value of the actual pattern is measured, and the master plate is evaluated in accordance with a measurement result. However, further investigation is required to improve the measurement accuracy of the feature value of the actual pattern.

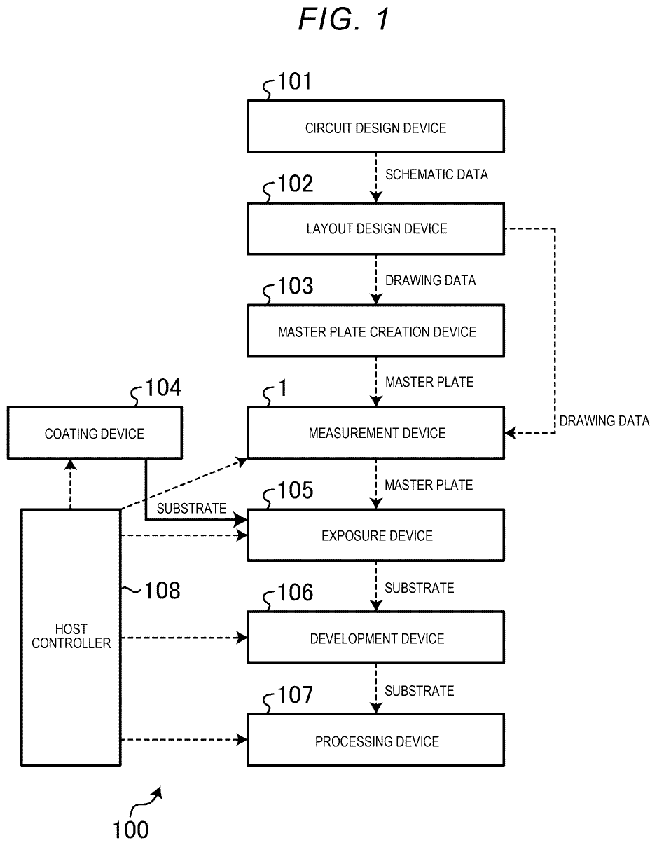

For example, a manufacturing system 100 including a measurement device 1 may be configured as shown in FIG. 1. FIG. 1 is a diagram showing a configuration of the manufacturing system 100 including the measurement device 1.

The manufacturing system 100 includes a circuit design device 101, a layout design device 102, a master plate creation device 103, a coating device 104, an exposure device 105, a development device 106, a processing device 107, a measurement device 1, and a host controller 108. The circuit design device 101 and the layout design device 102 may be implemented by one computer or may be implemented by a plurality of computers connected to each other to be capable of communicating with each other. For example, an electron beam drawing device may be used as the master plate creation device 103. The circuit design device 101, the layout design device 102, the master plate creation device 103, and the measurement device 1 may be connected to each other to be capable of communicating with each other via a communication line (not shown). The coating device 104, the exposure device 105, the development device 106, the processing device 107, the measurement device 1, and the host controller 108 may be connected to each other to be capable of communicating with each other via a communication line (not shown).

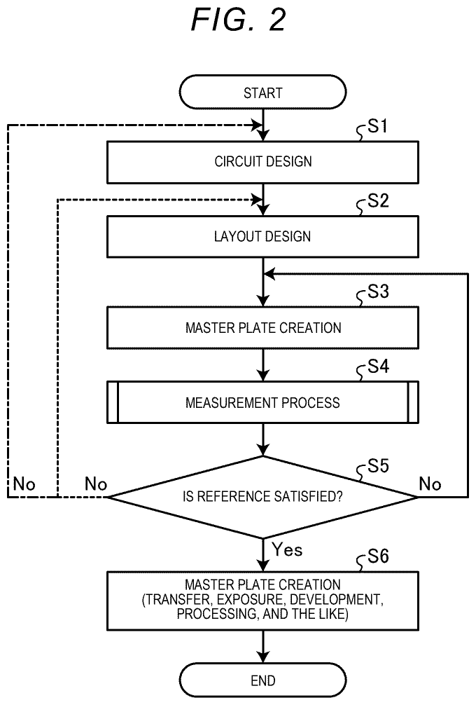

Further, the manufacturing system 100 operates as shown in FIG. 2. FIG. 2 is a flowchart showing an operation of the manufacturing system 100.

The circuit design device 101 performs circuit design based on predetermined design information and/or an instruction from a user (S1), generates schematic data, and supplies the schematic data to the layout design device 102.

The layout design device 102 performs a layout design based on the schematic data and/or the instruction from the user (S2), and generates layout data. The layout design device 102 further generates drawing data from the layout data based on the predetermined design information and/or the instruction from the user, and supplies the drawing data to each of the master plate creation device 103 and the measurement device 1. The master plate is, for example, a mask, a reticle, and the like.

The master plate creation device 103 draws a plurality of master plate patterns on a master plate substrate according to the drawing data to create a master plate (S3). The created master plate includes a plurality of master plate patterns (a plurality of actual patterns).

The master plate after creation is conveyed from the master plate creation device 103 to the measurement device 1 by a conveyance system (not shown). The measurement device 1 performs a measurement process on the master plate using the drawing data (S4).

For example, the measurement device 1 acquires image data including a plurality of actual patterns. The measurement device 1 may be a Critical Dimension Scanning Electron Microscope (CD-SEM) having an imaging device. The measurement device 1 may acquire image data IM1 including the plurality of actual patterns by imaging an SEM image of the master plate using the imaging device. The measurement device 1 sets a plurality of measurement regions ROI1 in the image data. The measurement device 1 measures the feature value of each of the plurality of measurement regions ROI1 by using the image data IM1, and forms an array AR1. The feature value is, for example, a dimension. The array AR1 includes a plurality of feature values, each of which is correlated with position information of the measurement region ROI1.

The measurement device 1 acquires design data including a plurality of design patterns from the layout design device 102. The measurement device 1 may acquire the drawing data as the design data from the layout design device 102. The measurement device 1 measures the feature value of each of the plurality of measurement regions ROI2 by using the design data, and forms the array AR2. The feature value is, for example, a dimension. The array AR1 includes a plurality of feature values, each of which is correlated with position information of the measurement region ROI2.

The measurement device 1 performs statistical process using the array AR1 and the array AR2. The measurement device 1 may generate a frequency distribution of the array AR1 and generate a frequency distribution of the array AR2. The measurement device 1 matches the plurality of actual patterns with the plurality of design patterns according to the result of the statistical process to obtain a desired feature value. For example, the measurement device 1 may compare the frequency distribution of the array AR1 with the frequency distribution of the array AR2, and may perform labeling on the array AR2 according to a comparison result. The measurement device 1 may extract a desired feature value according to a condition designated in advance from the plurality of labeled feature values.

The measurement device 1 evaluates the master plate according to the desired feature value and determines whether the master plate satisfies the reference (S5). The measurement device 1 may determine that the master plate satisfies the reference when the dimension of the actual pattern in the master plate is within an allowable range. The measurement device 1 may determine that the master plate does not satisfy the reference when the dimension of the actual pattern in the master plate is out of the allowable range. The measurement device 1 may notify the determination result to the host controller 108.

When the master plate does not satisfy the reference (No in S5), the master plate creation may be performed again as indicated by solid arrows in FIG. 2.

The master plate is conveyed from the measurement device 1 to a peeling device (not shown) by a conveyance system (not shown) under the control of the host controller 108, and a plurality of master plate patterns are peeled from the master plate substrate by the peeling device. The master plate substrate is conveyed from the peeling device to the master plate creation device 103 by the conveyance system (not shown), set in the master plate creation device 103, and S3 and S4 are performed again.

Alternatively, when the master plate does not satisfy the reference (No in S5), the layout design may be performed again as indicated by dotted arrows in FIG. 2.

The master plate is conveyed from the measurement device 1 to a peeling device (not shown) by a conveyance system (not shown) under the control of the host controller 108, and a plurality of master plate patterns are peeled from the master plate substrate by the peeling device. The master plate substrate is conveyed from the peeling device to the master plate creation device 103 by the conveyance system (not shown), set in the master plate creation device 103, and S2, S3, and S4 are performed again.

Alternatively, when the master plate does not satisfy the reference (No in S5), the circuit design may be performed again as indicated by one-dot chain line arrows in FIG. 2.

The master plate is conveyed from the measurement device 1 to a peeling device (not shown) by a conveyance system (not shown) under the control of the host controller 108, and a plurality of master plate patterns are peeled from the master plate substrate by the peeling device. The master plate substrate is conveyed from the peeling device to the master plate creation device 103 by the conveyance system (not shown), set in the master plate creation device 103, and S1, S2, S3, and S4 are performed again.

When the master plate satisfies the reference (Yes in S5), a plurality of actual patterns on the master plate are transferred to the substrate, and exposure, development, processing, and the like are performed to create the substrate (S6).

The master plate is conveyed from the measurement device 1 to the exposure device 105 by the conveyance system (not shown) and set on a master plate stage of the exposure device 105.

Meanwhile, the coating device 104 coats a photosensitive agent (for example, a resist) on the substrate (for example, a wafer). The substrate on which the photosensitive agent is applied is conveyed from the coating device 104 to the exposure device 105 by the conveyance system (not shown) and placed on a substrate stage of the exposure device 105. The exposure device 105 uses a projection optical system to form an image on the substrate using the exposure light illuminated by an illumination optical system and passes through the master plate or the exposure light that is reflected by the master plate, and transfers a plurality of actual patterns on the master plate to the photosensitive agent on the substrate to form a latent image.

The substrate after the exposure is conveyed from the exposure device 105 to the development device 106 by the conveyance system (not shown). The development device 106 develops the latent image in the photosensitive agent on the substrate. As a result, a pattern according to design information (drawing data) is developed in each shot region on the substrate.

The substrate after development is conveyed from the development device 106 to the processing device 107 by the conveyance system (not shown). The processing device 107 performs predetermined processing on the substrate using a pattern of the developed photosensitive agent as a mask. As a result, a pattern according to design information (drawing data) is formed in each shot region on the substrate.

The measurement process (S4) may be performed after the substrate creation (S6). In this case, a part of the substrates to be created may be selected, and the measurement process (S4) may be performed.

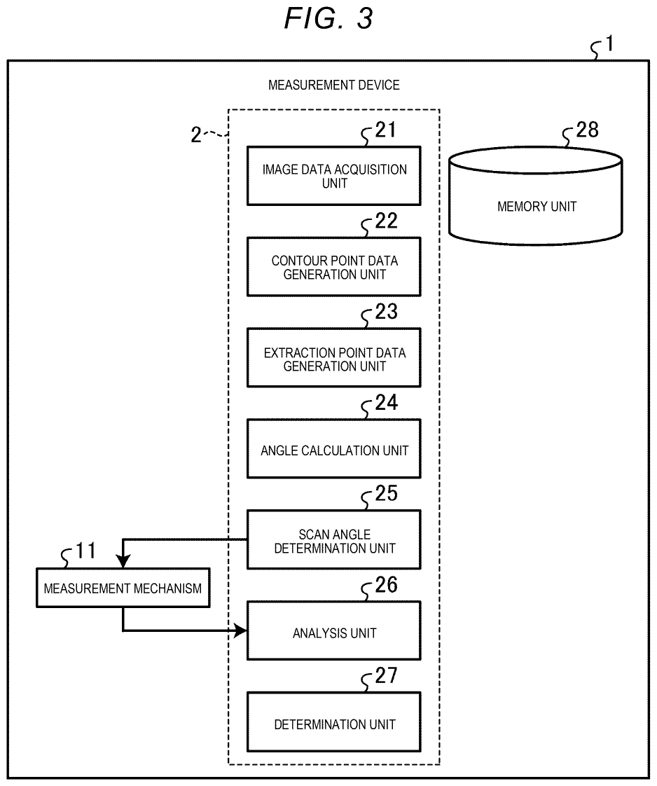

Next, a configuration of the measurement device 1 will be described with reference to FIG. 3. FIG. 3 is a block diagram showing a configuration of the measurement device 1.

The measurement device 1 is a device capable of measuring a shape of a pattern formed on a master plate substrate by scanning the pattern with an electron beam. Specifically, the measurement device 1 determines a scan angle of an electron beam with respect to the master plate substrate, scans the master plate substrate with the electron beam at the scan angle, and measures the shape of the pattern based on an imaging image generated as a result of the scanning. The measurement device 1 capable of executing such a measurement process is configured as, for example, a CD-SEM. The electron beam is an example of a charged particle.

The measurement device 1 includes a measurement mechanism 11, a controller 2, and a memory unit 28.

The controller 2 includes an image data acquisition unit 21, a contour point data generation unit 22, an extraction point data generation unit 23, an angle calculation unit 24, a scan angle determination unit 25, an analysis unit 26, and a determination unit 27. Each unit in the controller 2 may be entirely implemented by software, entirely implemented by hardware, or partially implemented by software and partially implemented by hardware. The memory unit 28 may be a storage such as an SSD or an HDD.

The controller 2 can control the measurement mechanism 11 to perform the measurement process (S4). The controller 2 can store the image data IM1 obtained in the measurement process (S4) in the memory unit 28. The controller 2 may be implemented with a system on chip (SoC).

The measurement mechanism 11 is a physical and mechanical configuration part of the measurement device 1. The measurement mechanism 11 irradiates the master plate substrate with an electron beam at a predetermined scan angle. The measurement mechanism 11 can use, for example, 0° which is a reference, or a scan angle, which is determined by the scan angle determination unit 25 to be described later, as a predetermined scan angle.

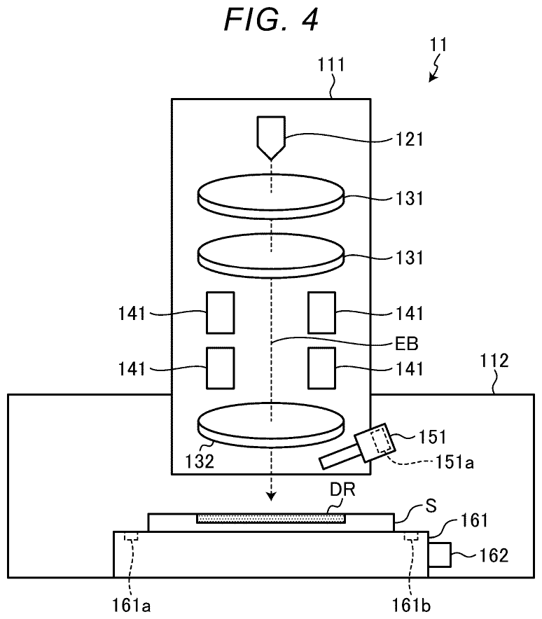

FIG. 4 is a diagram schematically showing an example of the configuration of the measurement mechanism 11. As shown in FIG. 4, the measurement mechanism 11 includes a lens barrel 111 in which an electron gun 121 serving as an irradiation source of the electron beam EB as the charged particles is provided, a sample chamber 112 in which the master plate substrate S is disposed, and a control unit that controls each unit of the measurement mechanism 11.

The lens barrel 111 has a cylindrical shape. The lens barrel 111 has a closed upper end portion and an open lower end portion through which the electron beam EB passes. The sample chamber 112 is configured to accommodate the master plate substrate S. The lens barrel 111 and the sample chamber 112 are combined in a state of being airtightly sealed. The inside of the lens barrel 111 and the inside of the sample chamber 112 are capable of being held at a reduced pressure by a pump or the like (not shown).

In the inside of the lens barrel 111, the electron gun 121, a converging lens 131, an object lens 132, a coil 141, and a detector 151 are provided in order from the vicinity of the upper end portion.

The electron gun 121 emits an electron beam EB toward a lower side in the lens barrel 111. The electron beam EB emitted from the electron gun 121 progresses along the longitudinal axis direction of the lens barrel 111.

The converging lens 131 is an electromagnetic coil wound concentrically around the optical axis of the lens barrel 111, and converges the electron beam EB by a magnetic field.

The object lens 132 is an electromagnetic coil wound concentrically around the optical axis of the lens barrel 111, and converges the electron beam EB emitted toward the master plate substrate S by a magnetic field.

The coil 141 is an electromagnetic coil that is a set of two coils for deflecting the converged electron beam EB or for performing astigmatism correction, and is disposed symmetrically with respect to the optical axis of the lens barrel 111. The coil 141 scans the converged electron beam EB on the device region R of the master plate substrate S at a predetermined scan angle. The predetermined scan angle is, for example, a scan angle determined by the scan angle determination unit 25 to be described later. Further, the coil 141 can scan the master plate substrate S with a plurality of electron beams EB.

The detector 151 detects secondary electrons or backscattered electrons obtained as a result of scanning the device region R at a predetermined scan angle. The detector 151 includes an imaging device 151a. The detector 151 acquires a two-dimensional intensity distribution of secondary electrons or backscattered electrons by using the imaging device 151a, and images the device region R. As a result, an imaging image of the device region R is generated.

A stage 161 on which the master plate substrate S is placed is provided in the sample chamber 112. The actuator 162 is attached to the stage 161, and the stage 161 is drivable forward and backward and right and left. The desired device region R on the master plate substrate S can be observed by driving the stage 161.

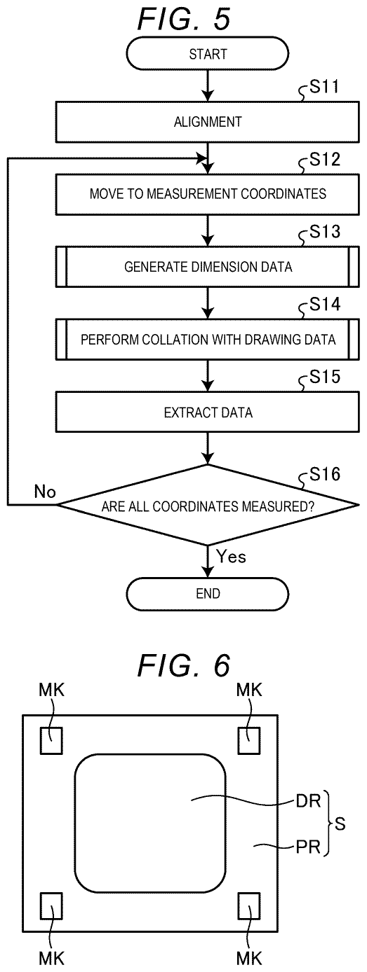

Next, details of the measurement process (S4) by the measurement device 1 will be described with reference to FIG. 5. FIG. 5 is a flowchart showing an operation of the measurement device 1.

When the master plate substrate S is placed on the stage 161, the measurement device 1 performs alignment of the master plate substrate S and the stage 161 (S11). The measurement device 1 may perform alignment using the mark MK provided on the master plate substrate S and the mark 161a provided on the stage 161.

For example, as shown in FIG. 6, the master plate substrate S has a device region DR and a peripheral region PR. FIG. 6 is a diagram showing a configuration of a measurement target.

A plurality of master plate patterns (a plurality of actual patterns) are formed in the device region DR. When the master plate is a transmission type, the plurality of actual patterns are, for example, a pattern of a light-shielding film on the master plate substrate. When the master plate is a reflection type, the plurality of actual patterns are, for example, a pattern of unevenness on the master plate substrate.

A plurality of marks MK are formed in the peripheral region PR. Although four marks MK are exemplified in FIG. 6, the number of marks MK may be equal to or less than three or equal to or greater than five as long as alignment is possible. Although FIG. 6 exemplifies a configuration in which the mark MK is formed at the four corners in the peripheral region PR, the formation position of the mark MK may be another position in the peripheral region PR as long as alignment is possible.

As shown in FIG. 4, a mark 161a may be provided in a periphery of a region on which the master plate substrate S is placed on the stage 161.

The measurement device 1 has an imaging device 1a (not shown), and can recognize the relative position of the master plate substrate S with respect to the stage 161 by imaging the mark MK of the master plate substrate S and the mark 161a of the stage 161 with the imaging device 1a. The measurement device 1 may obtain the deviation ΔPOS from the reference position of the position of the master plate substrate S according to the recognition result, and may drive the stage 161 in the XYZ directions by controlling the actuator 162 to cancel the deviation ΔPOS.

As a result, the position of the master plate substrate S can be aligned with a reference position in the measurement device 1.

When a measurement request is received from the host controller 108, the measurement device 1 moves to the measurement coordinates (S12). The measurement request includes a plurality of measurement coordinates and a condition to be guaranteed. The measurement device 1 acquires a plurality of measurement coordinates from the measurement request, and selects a measurement coordinate to be focused on from the plurality of measurement coordinates. The measurement device 1 may obtain a movement value ΔMV in the XYZ directions to the measurement coordinates, with a reference position aligned in S11 as a starting point. The measurement device 1 may drive the stage 161 in the XYZ directions by controlling the actuator 162 to move the master plate substrate S by a movement value ΔMV.

When moving to the measurement coordinates, the measurement device 1 performs the dimension data generation process (S13). The dimension data generation process is a process of measuring the dimension of the actual pattern included in the measurement region ROI1 and generating the measurement result as numerical dimension data.

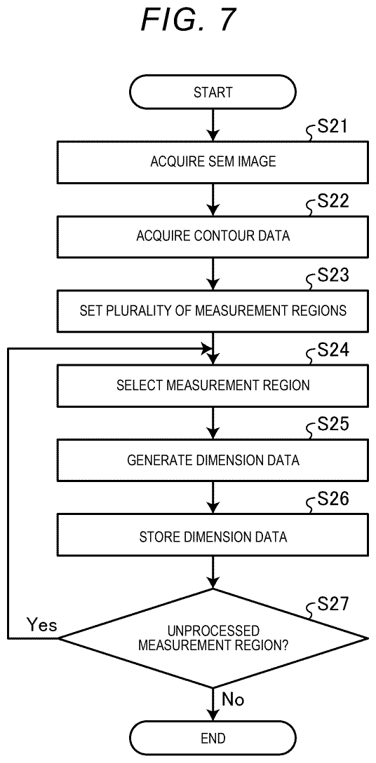

In the dimension data generation process (S13), S21 to S27 shown in FIG. 7 may be performed. FIG. 7 is a flowchart showing the dimension data generation process.

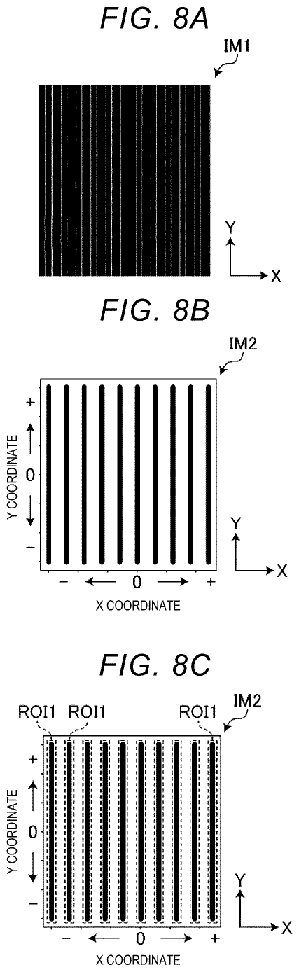

The measurement device 1 acquires an SEM image of the master plate (S21). The measurement device 1 may acquire the image data IM1 as shown in FIG. 8A by imaging the SEM image of the master plate using an imaging device. FIGS. 8A to 8C are diagrams showing the image data and the contour data.

In the image data IM1 shown in FIG. 8A, the pixel position and the brightness information are two-dimensionally correlated with respect to a plurality of pixels. A horizontal direction in FIG. 8A may be an X direction, and a vertical direction may be a Y direction. The image data IM1 may have a pixel position at the center thereof as an origin of the pixel coordinates.

The image data IM1 includes a plurality of actual patterns. In FIG. 8A, a line-and-space pattern in which a plurality of lines each extending in the Y direction are repeatedly arranged in the X direction with spaces therebetween is exemplified as the plurality of actual patterns.

The measurement device 1 acquires the contour data IM2 of a plurality of actual patterns using the image data IM1 (S22). The measurement device 1 may acquire the contour data IM2 as shown in FIG. 8B by performing an edge detection process on the image data IM1. The edge detection process can use a known method such as the Canny method. FIG. 8B shows the contour data IM2 of the measurement region ROI1. In FIG. 8B, a horizontal axis indicates an X coordinate, and a vertical axis indicates a Y coordinate.

In the contour data IM2 shown in FIG. 8B, the pixel position and the contour information are two-dimensionally correlated with respect to a plurality of pixels. The contour data IM2 corresponds to the image data IM1.

The contour data IM2 includes a plurality of contour patterns corresponding to a plurality of actual patterns. When the plurality of actual patterns are line-and-space patterns, the plurality of contour patterns may be line contour-and-space patterns. The line contour indicates a contour of the line pattern.

The measurement device 1 sets a plurality of measurement regions ROI1 with respect to the contour data IM2 (S23). The measurement device 1 may set a plurality of measurement regions ROI1 indicated by being surrounded by a dotted line in FIG. 8C according to the plurality of contour patterns. In a case where the plurality of contour patterns are line contour-and-space patterns, the measurement device 1 may set the measurement region ROI1 for each of the plurality of line contours.

The measurement device 1 may set each of the plurality of measurement regions ROI1 in a shape according to the contour pattern. When the contour pattern is a line contour, the measurement device 1 may set the measurement region ROI1 as a line shape.

The measurement device 1 may specify and store a pixel position at the center for each of the plurality of measurement regions ROI1.

When the plurality of measurement regions ROI1 are set, the measurement device 1 selects the measurement region ROI1 to be processed from among the plurality of measurement regions ROI1 (S24).

The measurement device 1 generates the dimension data by using the contour pattern of the measurement region ROI1 to be processed (S25). The measurement device 1 may obtain the line width by taking a difference between pixel positions of edges adjacent to each other in the X direction in the contour pattern of the measurement region ROI1 to be processed. The measurement device 1 may obtain the line widths at a plurality of different Y positions and take an average thereof. As a result, the measurement device 1 can generate the line width as the dimension data.

The measurement device 1 stores the generated dimension data (S26). The measurement device 1 may store the dimension data by generating or updating the array AR1 including the dimension data in a form correlated with the position information of the measurement region ROI1. The array AR1 returns the dimension data when the position information of the measurement region ROI1 is given. The dimension data includes, for example, a line width.

When there is an unprocessed measurement region ROI1 among the plurality of measurement regions ROI1 (Yes in S27), the measurement device 1 returns the process to S24.

When there is no unprocessed measurement region ROI1 among the plurality of measurement regions ROI1 (No in S27), the measurement device 1 ends the process.

When the dimension data generation process (S13) is completed, the measurement device 1 performs collation with drawing data (S14). The collation with the drawing data can be rephrased as a collation between the image data including the plurality of actual patterns and the drawing data including the plurality of design patterns, and can be regarded as a matching between the plurality of actual patterns and the plurality of design patterns.

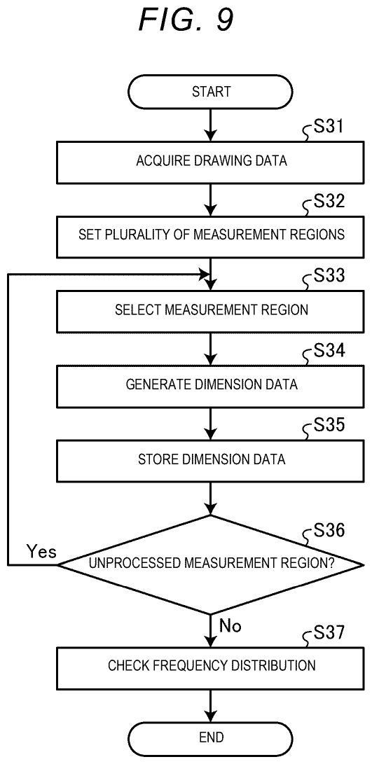

In the collation with the drawing data (S14), S31 to S37 shown in FIG. 9 may be performed. FIG. 9 is a flowchart showing collation with the drawing data.

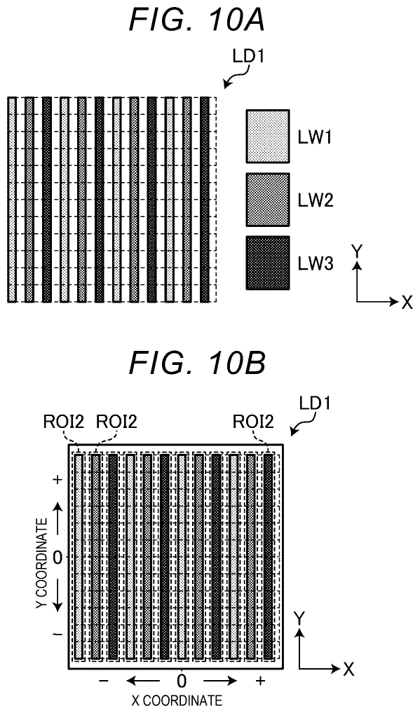

The measurement device 1 acquires the drawing data (S31). The measurement device 1 may acquire drawing data LD1 as shown in FIG. 10A from the layout design device 102. FIGS. 10A and 10B are diagrams showing the drawing data.

In the drawing data LD1 shown in FIG. 10A, the pixel positions and the drawing information are two-dimensionally correlated with respect to a plurality of pixels. A horizontal direction in FIG. 10A may be an X direction, and a vertical direction may be a Y direction. The drawing data LD1 may have a pixel position at the center thereof as an origin of the pixel coordinates.

The drawing data LD1 includes a plurality of design patterns. In FIG. 10A, a line-and-space pattern in which a plurality of lines each extending in the Y direction are repeatedly arranged in the X direction with spaces therebetween is exemplified as the plurality of design patterns. A design value of a line width is associated with each design pattern. In FIG. 10A, a line width LW1 is associated with the lines with thin hatching. A line width LW3 is associated with the lines with dark hatching. A line width LW2 is associated with the lines with medium density hatching.

The measurement device 1 sets a plurality of measurement regions ROI2 for the drawing data LD1 (S32). The measurement device 1 may set a plurality of measurement regions ROI2 indicated by being surrounded by dotted lines in FIG. 10B according to the plurality of design patterns. When the plurality of design patterns are line-and-space patterns, the measurement device 1 may set the measurement region ROI2 for each of the plurality of design patterns. The measurement device 1 may specify and store a pixel position at the center for each of the plurality of measurement regions ROI2.

When the plurality of measurement regions ROI2 are set, the measurement device 1 selects the measurement region ROI2 to be processed from among the plurality of measurement regions ROI2 (S33).

The measurement device 1 generates the dimension data by using the design pattern of the measurement region ROI2 to be processed (S34). The measurement device 1 may acquire a design value of a line width associated with the design pattern of the measurement region ROI2 to be processed. As a result, the measurement device 1 can generate the line width as the dimension data.

The measurement device 1 stores the generated dimension data (S35). The measurement device 1 may store the dimension data by generating or updating the array AR2 including the dimension data in a form correlated with the position information of the measurement region ROI2. The array AR2 returns the dimension data when the position information of the measurement region ROI2 is given. The dimension data includes, for example, a line width.

When there is an unprocessed measurement region ROI2 among the plurality of measurement regions ROI2 (Yes in S36), the measurement device 1 returns to the process in S33.

When there is no unprocessed measurement region ROI2 among the plurality of measurement regions ROI2 (No in S36), the measurement device 1 performs the statistical process using the array AR1 and the array AR2. The measurement device 1 generates a frequency distribution of the array AR1, generates a frequency distribution of the array AR2, and performs a frequency distribution checking process of checking the frequency distribution of the array AR1 with the frequency distribution of the array AR2 (S37).

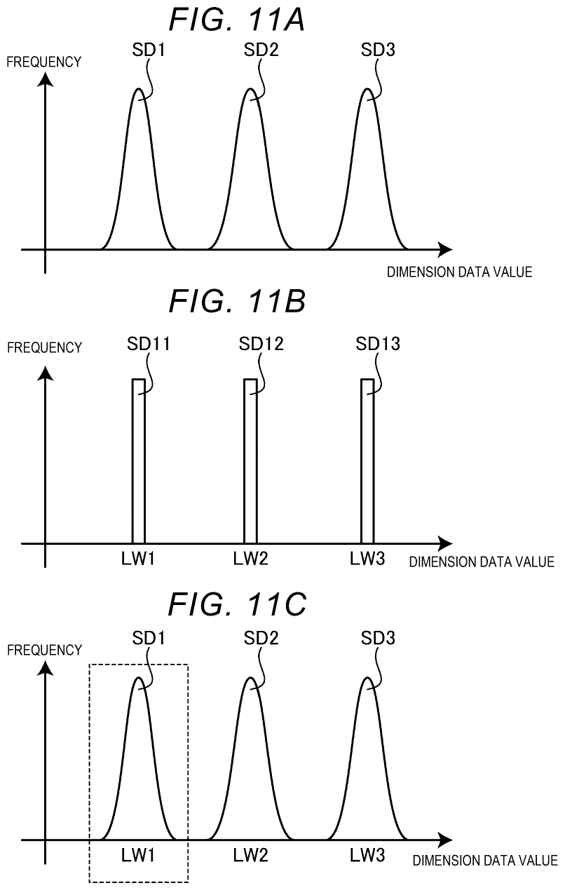

For example, the measurement device 1 sequentially gives the position information of the plurality of measurement regions ROI1 with respect to the array AR1, extracts the dimension data of the plurality of measurement regions ROI1, and adds the dimension data to the frequency and dimension data value plane. As a result, the measurement device 1 can generate the frequency distribution of the array AR1 as shown in FIG. 11A. FIGS. 11A to 11C are diagrams showing the check of the frequency distribution.

In FIG. 11A, a vertical axis indicates a frequency, and a horizontal axis indicates a dimension data value. In the example of FIG. 11A, three distributions, that is, a distribution SD1, a distribution SD2, and a distribution SD3 are generated in ascending order of the dimension data value. Each of the distributions SD1 to SD3 has a mountain-like spread. The center of each distribution SD1 to SD3 may be represented by a dimension data value having the maximum frequency. The width of each distribution SD1 to SD3 can be represented by a half-value width corresponding to a difference between the dimension data values at which the frequency is half the maximum.

The measurement device 1 sequentially gives the position information of the plurality of measurement regions ROI2 with respect to the array AR2, extracts the dimension data of the plurality of measurement regions ROI2, and adds the dimension data to the frequency and dimension data value plane. As a result, the measurement device 1 can generate the frequency distribution of the array AR2 as shown in FIG. 11B.

In FIG. 11B, a vertical axis indicates a frequency, and a horizontal axis indicates a dimension data value. In the example of FIG. 11B, three distributions, that is, a distribution SD11, a distribution SD12, and a distribution SD13 are generated from the side where the dimension data value is low. Each of the distributions SD11 to SD13 does not have a spread in a line shape and indicates the dimension data value at a point. The respective distributions SD11 to SD13 indicate a line width LW1, a line width LW2, and a line width LW3 from a side where the dimension data value is low.

The measurement device 1 may compare a frequency distribution of the array AR1 with a frequency distribution of the array AR2, and may perform labeling on the frequency distribution of the array AR2 according to a comparison result.

The measurement device 1 compares the frequency distribution shown in FIG. 11A with the frequency distribution shown in FIG. 11B, and confirms that FIG. 11A and FIG. 11B are consistent in a fact that both the three distributions SD1 to SD3 and SD11 to SD13 exist. Accordingly, as shown in FIG. 11C, the measurement device 1 can assign the line width LW1, the line width LW2, and the line width LW3 to the distribution SD1, the distribution SD2, and the distribution SD3, respectively, as representative values of the dimension data indicated by the distribution SD1, the distribution SD2, and the distribution SD3 from the side where the dimension data value is low. That is, the measurement device 1 can label the line width LW1, the line width LW2, and the line width LW3 on the distribution SD1, the distribution SD2, and the distribution SD3.

When the collation with the drawing data is completed (S14), the measurement device 1 performs data extraction (S15). The measurement device 1 extracts the condition to be guaranteed from the measurement request received in S12. The measurement device 1 extracts a dimension data value group according to the condition to be guaranteed in the frequency distribution of the array AR2. For example, when the condition to be guaranteed is the dimension data value group having the lowest condition, the measurement device 1 can extract the distribution SD1 indicated by being surrounded by a dotted line in FIG. 11C as the dimension data value group according to the condition to be guaranteed.

The measurement device 1 determines whether all the plurality of measurement coordinates acquired from the measurement request are measured (S16). When there is an unmeasured measurement coordinate (No in S16), the measurement device 1 returns to the process in S12, and when there is no unmeasured measurement coordinate (Yes in S16), the measurement device 1 ends the process.

As described above, in the first embodiment, in the measurement method, the feature value of each of the plurality of measurement regions ROI1 set in the image data including the plurality of actual patterns is measured, and the array AR1 is formed. The feature value of each of the plurality of measurement regions ROI2 set in the design data including the plurality of design patterns is measured, and the array AR2 is formed. The statistical process is performed using the array AR1 and the array AR2, and matching between the plurality of actual patterns and the plurality of design patterns is performed according to a result of the statistical process. As a result, since the matching with the design data in the measurement of the feature value of the actual pattern can be performed numerically, the measurement accuracy of the feature value of the actual pattern can be improved.

### Second Embodiment

Next, a measurement method according to a second embodiment will be described. Hereinafter, portions different from the first embodiment will be mainly described.

Although the collation with the drawing data using the frequency distribution is exemplified in the first embodiment, the collation with the drawing data using a correlation coefficient is exemplified in the second embodiment.

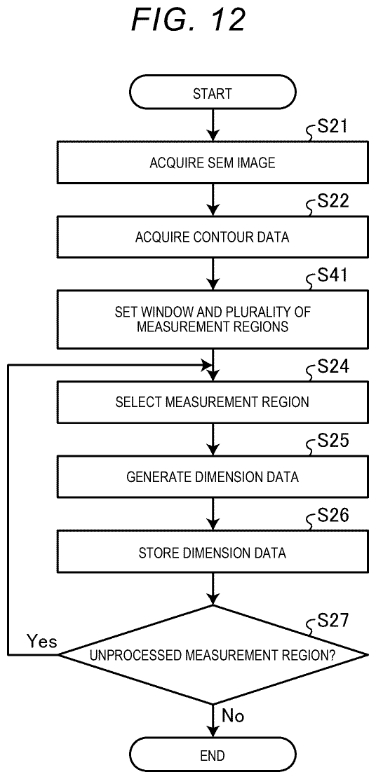

In a dimension data generation process (S13) in the measurement process (S4), as shown in FIG. 12, a process different from the first embodiment in the following points is performed. FIG. 12 is a flowchart showing the dimension data generation process in the second embodiment.

After the processes in S21 and S22 are performed in the same manner as in the first embodiment, the measurement device 1 sets a window WD1 and a plurality of measurement regions ROI1 with respect to a contour data IM2 (S41).

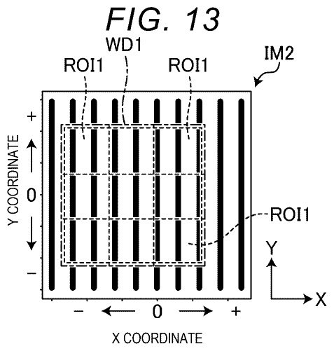

The measurement device 1 may set the window WD1 indicated by being surrounded by one-dot chain line in FIG. 13 with respect to the contour data IM2. An X width of the window WD1 is smaller than an X width of the contour data IM2. A Y width of the window WD1 is smaller than a Y width of the contour data IM2. The window WD1 may be set to include the plurality of contour patterns.

The measurement device 1 may set a plurality of measurement regions ROI1 in the window WD1. The measurement device 1 may set each of the plurality of measurement regions ROI1 in a shape according to the window WD1. When the window WD1 is set in a rectangular shape, the measurement device 1 may set a rectangular measurement region ROI1.

Although FIG. 13 exemplifies a case where 9 (=3×3) measurement regions ROI1 are set in the window WD1, more measurement regions ROI1 may be set in the window WD1. A plurality of rectangular intervals having a unit length may be set as the measurement region ROI1 in the window WD1.

Thereafter, S24 to S27 are performed in the same manner as in the first embodiment.

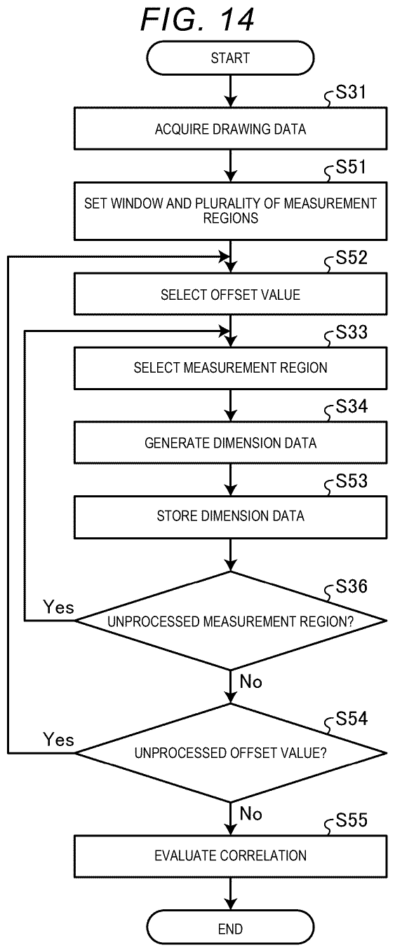

In the collation (S14) with the drawing data in the measurement process (S4), as shown in FIG. 14, a process different from the first embodiment in the following points is performed. FIG. 14 is a flowchart showing a process of collating the drawing data according to the second embodiment.

After S31 is performed in the same manner as in the first embodiment, the measurement device 1 sets the window WD2 and the plurality of measurement regions ROI2 with respect to the drawing data LD1 (S41).

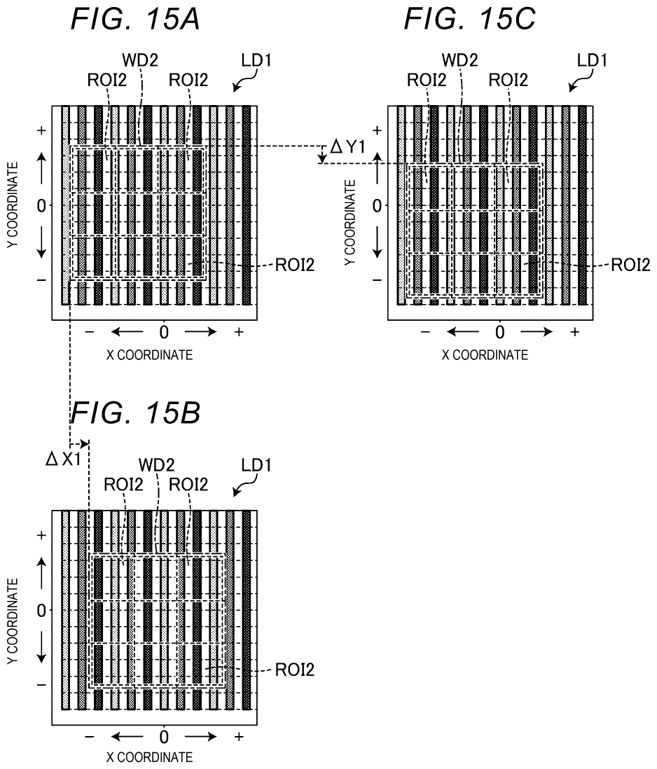

The measurement device 1 may set the window WD2 indicated by being surrounded by one-dot chain line in FIG. 15A with respect to the drawing data LD1. The measurement device 1 may set the window WD2 to have a shape and a size corresponding to the window WD1. An X width of the window WD2 is smaller than an X width of the drawing data LD1. A Y width of the window WD2 is smaller than a Y width of the drawing data LD1. The window WD2 may be set to include a plurality of design patterns.

The measurement device 1 may set a plurality of measurement regions ROI2 in the window WD2. The measurement device 1 may set each of the plurality of measurement regions ROI2 in a shape according to the window WD2. When the window WD2 is set in a rectangular shape, the measurement device 1 may set a rectangular measurement region ROI2.

Although FIG. 15A exemplifies a case where 9 (=3×3) measurement regions ROI2 are set in the window WD2, more measurement regions ROI2 may be set in the window WD2. A plurality of square sections having a unit length may be set in the window WD2 as the measurement region ROI2.

Thereafter, S24 to S27 are performed in the same manner as in the first embodiment.

The measurement device 1 offsets the position of the window WD2 in the drawing data LD1 while fixing the position of the window WD1 in the contour data IM2 to see the correlation with the contour data IM2. This corresponds to offset the position of the window WD2 with respect to the position of the window WD1.

The measurement device 1 may prepare a plurality of offset values as candidates for the offset value of the window WD2. The measurement device 1 may prepare a combination of a plurality of X offset values and a plurality of Y offset values. For example, the measurement device 1 prepares six X offset values ΔX0, ΔX1, ΔX2, ΔX3, ΔX4, and ΔX5. The measurement device 1 prepares six Y offset values ΔY0, ΔY1, ΔY2, ΔY3, ΔY4, and ΔY5. As a result, 6×6=36 offset values are prepared. The offset values may satisfy the following Expressions 1 and 2.

$$Δ X θ ( = θ ) < Δ X 1 < Δ X 2 < Δ X 3 < Δ X 4 < Δ X 5 \qquad Expression 1$$

$$Δ Y θ ( = θ ) < Δ Y 1 < Δ Y 2 < Δ Y 3 < Δ Y 4 < Δ Y 5 \qquad Expression 2$$

The number of offset values is not limited to this number, and any number of offset values may be used as an appropriate number for viewing the correlation.

When a plurality of offset values are prepared, the measurement device 1 selects the offset value to be processed from among the plurality of measurement regions ROI2 (S52).

For example, when the X offset value ΔX0 and the Y offset value ΔY0 are selected, as shown in FIG. 15A, the window WD2 is disposed at the initial position in the drawing data LD1, and the plurality of measurement regions ROI2 are disposed in the window WD2.

Alternatively, when the X offset value ΔX1 and the Y offset value ΔY0 are selected, as shown in FIG. 15B, the window WD2 is disposed at a position obtained by offsetting the initial position of the drawing data LD1 in the X direction by the offset value ΔX1, and the plurality of measurement regions ROI2 are disposed in the window WD2.

Alternatively, when the X offset value ΔX0 and the Y offset value ΔY1 are selected, as shown in FIG. 15C, the window WD2 is disposed at a position obtained by offsetting the initial position of the drawing data LD1 in the Y direction by the offset value ΔY1, and the plurality of measurement regions ROI2 are disposed in the window WD2.

After S33 to S34 are performed in the same manner as in the first embodiment, the measurement device 1 stores the generated dimension data (S53). The measurement device 1 may store the dimension data by generating or updating the array AR2 including the dimension data in a shape associated with the X offset value of the window WD2, the Y offset value of the window WD2, and the relative position information of the measurement region ROI2 in the window WD2. The array AR2 returns the dimension data when the X offset value of the window WD2, the Y offset value of the window WD2, and the relative position information of the measurement region ROI2 in the window WD2 are given. The dimension data includes, for example, a line width.

S36 is performed in the same manner as in the first embodiment.

When there is an unprocessed offset value among the plurality of offset values (Yes in S54), the measurement device 1 returns to S52.

When there is no unprocessed offset value among the plurality of offset values (No in S54), the measurement device 1 performs statistical process using the array AR1 and the array AR2. The measurement device 1 performs an evaluation of correlation for obtaining a correlation coefficient between the array AR1 and the array AR2 (S54). The measurement device 1 may obtain the correlation coefficient between the array AR1 and the array AR2 for each of the offset values at the plurality of positions.

For example, the measurement device 1 selects the offset value to be processed from among the plurality of offset values. The offset value of the processing target includes an X offset value to be processed and a Y offset value to be processed.

The measurement device 1 subsequently gives the position information of the plurality of measurement regions ROI1 in the window WD1 with respect to the array AR1, and extracts the dimension data of the plurality of measurement regions ROI1.

The measurement device 1 gives the X offset value and the Y offset value to be processed with respect to the array AR1, subsequently gives the position information of the plurality of measurement regions ROI2 in the window WD2, and extracts the dimension data of the plurality of measurement regions ROI2.

The measurement device 1 obtains an average value AV1 of the dimension data of the plurality of measurement regions ROI1. The measurement device 1 obtains an average value AV2 of the dimension data of the plurality of measurement regions ROI2.

The measurement device 1 obtains a deviation DE1 of the dimension data of the plurality of measurement regions ROI1. The measurement device 1 obtains a deviation DE2 of the dimension data of the plurality of measurement regions ROI2.

The measurement device 1 divides the sum of squares of the deviations DE1 by the number of pieces of the dimension data to obtain a variance σ₁² of the dimension data of the plurality of measurement regions ROI1. The measurement device 1 divides the sum of squares of the deviations DE2 by the number of pieces of the dimension data to obtain the variance σ₂² of the dimension data of the plurality of measurement regions ROI2.

The measurement device 1 takes a positive square root of the variance σ₁² and obtains the standard deviation σ₁ of the dimension data of the plurality of measurement regions ROI1. The measurement device 1 takes a positive square root of the variance σ₂² and obtains the standard deviation σ₂ of the dimension data of the plurality of measurement regions ROI2.

The measurement device 1 divides a product of the deviation DE1 and the deviation DE2 by the number of pieces of the dimension data to obtain a covariance σ₁₂ between the dimension data of the plurality of measurement regions ROI1 and the dimension data of the plurality of measurement regions ROI2.

The measurement device 1 divides the covariance σ₁₂ by the product of the standard deviation σ₁ and the standard deviation σ₂, and obtains the correlation coefficient r between the dimension data of the plurality of measurement regions ROI1 and the dimension data of the plurality of measurement regions ROI2.

The measurement device 1 plots the data series of the X offset value on the correlation coefficient and Y offset value plane.

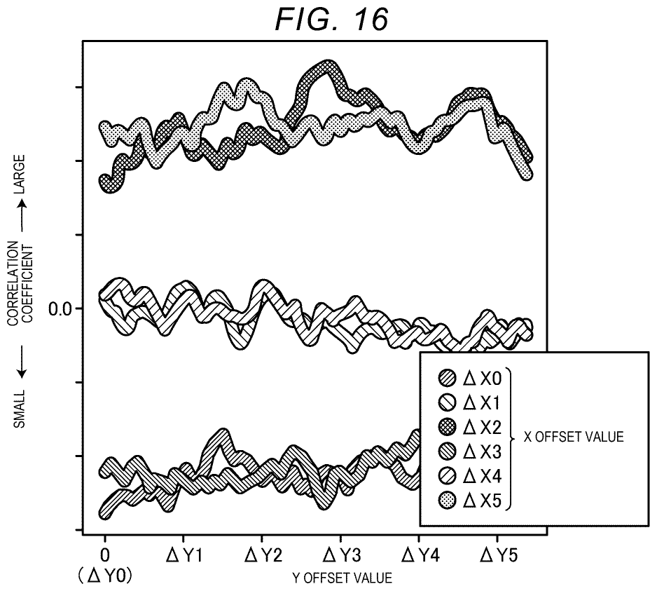

The measurement device 1 repeatedly performs these processes while changing the offset value to be processed, which is selected from among a plurality of offset values. As a result, the measurement device 1 can generate a graph in which the correlation coefficients for the plurality of offset values as shown in FIG. 16 are plotted. FIG. 16 is a diagram showing an evaluation of correlation.

Referring to the graph of FIG. 16, the offset value (a set of an X offset value and a Y offset value) corresponding to the highest correlation coefficient indicates a set of a position of the window WD1 having the highest correlation and a position of the window WD2 having the highest correlation. A position of the window WD1 and a position of the window WD2 having the highest correlation can be specified.

In the case of FIG. 16, the position of the window WD1 and the position of the window WD2 are most correlated with each other when the X offset value=ΔX2 and the Y offset value=ΔY3.

The measurement device 1 may perform labeling with respect to a plurality of actual patterns based on the correlation coefficient. The measurement device 1 may perform labeling with respect to the plurality of actual patterns according to the offset value of the position determined based on the correlation coefficient with respect to the offset value at the plurality of positions.

For example, the measurement device 1 acquires the contour pattern in the window WD1. The measurement device 1 offsets the window WD2 by using the offset value (a set of the X offset value and the Y offset value) with the highest correlation coefficient, and acquires the design pattern in the window WD2. The measurement device 1 can label the contour pattern in the window WD1 by comparing the contour pattern in the window WD1 with the design pattern in the window WD2.

As described above, in the second embodiment, in the measurement method, the feature value of each of the plurality of measurement regions ROI1 set in the image data including the plurality of actual patterns is measured, and the array AR1 is formed. The feature value of each of the plurality of measurement regions ROI2 set in the design data including the plurality of design patterns is measured, and the array AR2 is formed. The statistical process is performed using the array AR1 and the array AR2, and matching between the plurality of actual patterns and the plurality of design patterns is performed according to a result of the statistical process. As a result, since the matching with the design data in the measurement of the feature value of the actual pattern can be performed numerically, the measurement accuracy of the feature value of the actual pattern can be improved.

### Third Embodiment

Next, a measurement method according to a third embodiment will be described. Hereinafter, portions different from the first embodiment and the second embodiment will be mainly described.

Although numerical matching is exemplified in the first embodiment and the second embodiment, the use of numerical matching and image-based matching is exemplified in the third embodiment.

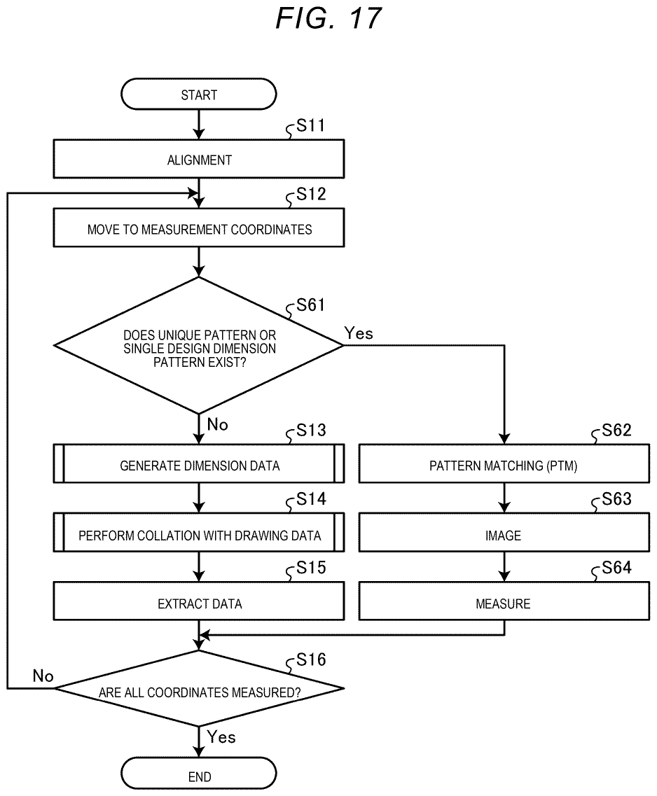

In the measurement process (S4), as shown in FIG. 17, a process different from the first embodiment in the following points is performed. FIG. 17 is a flowchart showing a measurement process in the third embodiment.

After S11 and S12 are performed in the same manner as in the first embodiment, the measurement device 1 refers to the drawing data and determines whether there is a unique pattern or a single design dimension pattern in the plurality of design patterns included in the drawing data (S61). The measurement device 1 can determine that there is no unique pattern in the plurality of design patterns when the plurality of design patterns are regularly repeated patterns such as a line-and-space pattern. The measurement device 1 can determine that there is a unique pattern in the plurality of design patterns when the plurality of design patterns are irregular patterns such as lines and holes arranged near the circuit element. The measurement device 1 can determine that there is a single design dimensional pattern when a plurality of design patterns are patterns in which the same pattern is repeated.

When there is no unique pattern in the plurality of design patterns (No in S61), the measurement device 1 performs the dimension data generation process (S13).

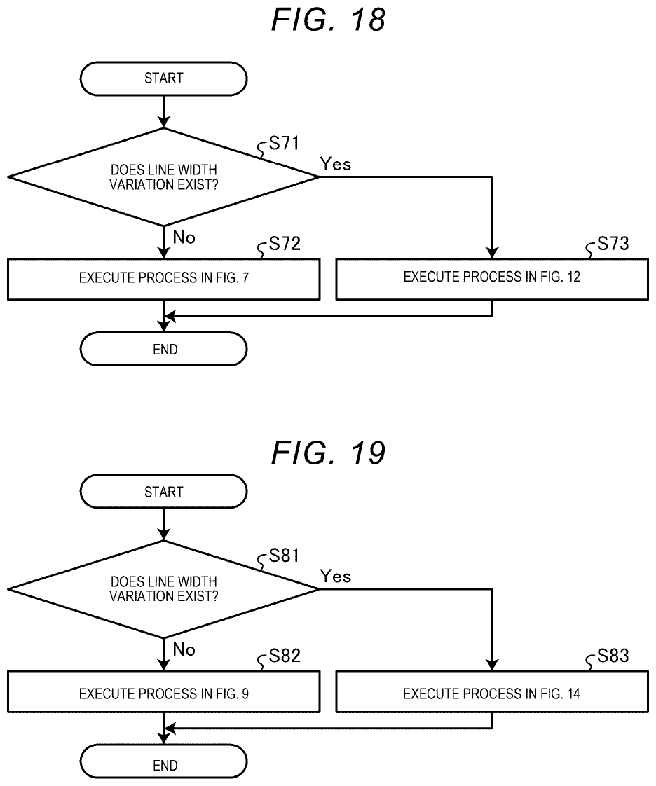

In the dimension data generation process (S13), the process may be performed as shown in FIG. 18. FIG. 18 is a flowchart showing a dimension data generation process in the third embodiment.

The measurement device 1 refers to the drawing data and determines whether there is a line width variation in a plurality of design patterns included in the drawing data (S71). In a case of a line-and-space pattern in which a line having the plurality of design patterns extending in the Y direction is repeatedly arranged in the X direction, the measurement device 1 can determine that there is a line width variation in the plurality of design patterns when the design line width changes when the line is viewed in the Y direction. When the line is viewed in the Y direction, the measurement device 1 can determine that there is no line width variation in the plurality of design patterns when the design line width is constant.

When there is no line width variation in the plurality of design patterns included in the drawing data (No in S71), the measurement device 1 performs the process in FIG. 7 in the same manner as in the first embodiment (S72).

When there is the line width variation in the plurality of design patterns included in the drawing data (Yes in S71), the measurement device 1 performs the process in FIG. 12 in the same manner as in the second embodiment (S73).

When the dimension data generation process (S13) is completed, the measurement device 1 performs collation with drawing data (S14).

In the collation with the drawing data (S14), the process as shown in FIG. 19 may be performed. FIG. 19 is a flowchart showing the collation with the drawing data in the third embodiment.

The measurement device 1 refers to the drawing data and determines whether there is the line width variation in the plurality of design patterns included in the drawing data (S81). In a case of a line-and-space pattern in which a line having the plurality of design patterns extending in the Y direction is repeatedly arranged in the X direction, the measurement device 1 can determine that there is a line width variation in the plurality of design patterns when the design line width changes when the line is viewed in the Y direction. When the line is viewed in the Y direction, the measurement device 1 can determine that there is no line width variation in the plurality of design patterns when the design line width is constant.

When there is no line width variation in the plurality of design patterns included in the drawing data (No in S81), the measurement device 1 performs the process in FIG. 9 in the same manner as in the first embodiment (S92).

When there is the line width variation in the plurality of design patterns included in the drawing data (Yes in S81), the measurement device 1 performs the process in FIG. 12 in the same manner as in the second embodiment (S83).

When the collation with the drawing data is completed (S14), the measurement device 1 performs S15 in the same manner as in the first embodiment.

When there is a unique pattern in the plurality of design patterns (Yes in S61), the measurement device 1 performs pattern matching (PTM) which is image-based matching (S62).

In pattern matching (S62), the measurement device 1 images an SEM image of the master plate (S21) and acquires the imaged SEM image as the image data IM1 in the same manner as in the process shown in FIG. 7, and acquires the contour data IM2 of the plurality of actual patterns by using the image data IM1 (S22). In the contour data IM2, for example, XY coordinates with a center as an origin are set. The contour data IM2 includes a plurality of contour patterns.

The measurement device 1 acquires the drawing data LD1 (S31) in the same manner as the process shown in FIG. 9. In the drawing data LD1, for example, XY coordinates with a center as an origin are set. The drawing data LD1 includes a plurality of design patterns.

The measurement device 1 uses the pixel positions of the edges of the contour pattern in the contour data IM2 and pixel positions of the edges of the design pattern in the drawing data LD1 to obtain an amount of deviation between the origin of the XY coordinates of the contour data IM2 and the origin of the XY coordinates of the drawing data LD1.

The measurement device 1 may control the coil 141 to correct the deflection direction of the electron beam EB such that the required amount of deviation is cancelled, and shift the SEM image. Alternatively, the measurement device 1 may control the actuator 162 to move the stage 161 in the XY direction such that the amount of deviation is cancelled.

As a result, the measurement device 1 can perform pattern matching between the contour pattern in the contour data IM2 and the design pattern in the drawing data LD1.

When pattern matching (S62) is completed, the measurement device 1 images the SEM image of the master plate (S63), acquires the SEM image as the image data IM1, and performs measurement to measure the dimensions of the plurality of actual patterns included in the image data IM1 (S64).

The measurement device 1 determines whether all the plurality of measurement coordinates acquired from the measurement request are measured (S16). When there is an unmeasured measurement coordinate (No in S16), the measurement device 1 returns to the process in S12, and when there is no unmeasured measurement coordinate (Yes in S16), the measurement device 1 ends the process.

As described above, in the third embodiment, in the measurement method, numerical matching is performed when there is no unique pattern in the plurality of design patterns, and image-based matching is performed when there is a unique pattern in the plurality of design patterns. As a result, numerical matching and image-based matching can be used selectively.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A measurement method comprising:
acquiring image data including a plurality of first patterns;
identifying a plurality of first measurement regions in the image data;
measuring a feature value of each of the plurality of first measurement regions using the image data, and forming a first array;
acquiring design data including a plurality of second patterns;
identifying a plurality of second measurement regions in the design data;
measuring a feature value of each of the plurality of second measurement regions using the design data, and forming a second array;
performing a statistical process using the first array and the second array; and
based on a result of the statistical process, obtaining a desired feature value by matching the plurality of first patterns with the plurality of second patterns.

2. The measurement method according to claim 1,
wherein the performing of the statistical process includes:
generating a frequency distribution of the first array; and
generating a frequency distribution of the second array.

3. The measurement method according to claim 2,
wherein the obtaining of the desired feature value by matching includes:
comparing the frequency distribution of the first array with the frequency distribution of the second array; and
performing labeling of the frequency distribution of the second array according to a comparison result.

4. The measurement method according to claim 1,
wherein the performing of the statistical process includes obtaining a correlation coefficient between the first array and the second array.

5. The measurement method according to claim 4,
wherein the obtaining of the desired feature value by matching includes performing labeling with respect to the plurality of first patterns based on the correlation coefficient.

6. The measurement method according to claim 4,
wherein the setting of the plurality of second measurement regions is performed for each of offset values of a plurality of positions different from each other between the plurality of first measurement regions and the plurality of second measurement regions, and
the performing of the statistical process includes obtaining the correlation coefficient between the first array and the second array with respect to each of the offset values of the plurality of positions.

7. The measurement method according to claim 6,
wherein the obtaining of the desired feature value by matching includes:
determining an offset value of a position based on the correlation coefficient with respect to the offset values of the plurality of positions; and
performing labeling with respect to the plurality of first patterns according to the determined offset value of the position.

8. A measurement device comprising:
a measurement mechanism; and
a controller operatively coupled to the measurement mechanism,
wherein the controller is configured to:
acquire image data including a plurality of first patterns;
identify a plurality of first measurement regions in the image data;
measure a feature value of each of the plurality of first measurement regions using the image data to form a first array;
acquire design data including a plurality of second patterns;
identify a plurality of second measurement regions in the design data;
measure a feature value of each of the plurality of second measurement regions using the design data to form a second array;
perform a statistical process using the first array and the second array; and
based on a result of the statistical process, obtain a desired feature value by matching the plurality of first patterns with the plurality of second patterns.

9. A master plate manufacturing method comprising:
creating a master plate including a plurality of first patterns;
imaging the master plate to acquire image data including the plurality of first patterns;
identifying a plurality of first measurement regions in the image data;
measuring a feature value of each of the plurality of first measurement regions using the image data, and forming a first array;
acquiring design data including a plurality of second patterns;
identifying a plurality of second measurement regions in the design data;
measuring a feature value of each of the plurality of second measurement regions using the design data, and forming a second array;
performing a statistical process using the first array and the second array;
based on a result of the statistical process, obtaining a desired feature value by matching the plurality of first patterns with the plurality of second patterns; and
evaluating the master plate according to the desired feature value.

10. A semiconductor device manufacturing method comprising:
creating a master plate including a plurality of first patterns;
imaging the master plate to acquire image data including the plurality of first patterns;
identifying a plurality of first measurement regions in the image data;
measuring a feature value of each of the plurality of first measurement regions using the image data, and forming a first array;
acquiring design data including a plurality of second patterns;
identifying a plurality of second measurement regions in the design data;
measuring a feature value of each of the plurality of second measurement regions using the design data, and forming a second array;
performing a statistical process by using the first array and the second array;
based on a result of the statistical process, obtaining a desired feature value by matching the plurality of first patterns with the plurality of second patterns;
evaluating the master plate according to the desired feature value; and
transferring the plurality of first patterns on the master plate to a substrate according to an evaluation result.
